(19) United States
(12) Patent Application Publication
(10) Pub. No.: US 2015/0259797 A1
(43) Pub. Date: Sep. 17, 2015

(54) Liquid-Metal Organic Compound Supply System

(71) Applicant: Jiangsu Nata Opto-electronic Material Co., Ltd., Suzhou (CN)

(72) Inventors: Bao-Yuan LU, Nanjing (CN); Ping LU, Suzhou Industrial Park (CN); Yi-Jing SHAN, Suzhou (CN); Bin SHEN, Suzhou (CN); Shuen-Ta TENG, Taoyuan County (TW)

(21) Appl. No.: 14/316,388

(22) Filed: Jun. 26, 2014

(30) Foreign Application Priority Data
Mar. 17, 2014 (TW) 103109882

(51) Int. Cl. C23C 16/455; F16K 11/00; C23C 16/18; F17D 3/00

(52) U.S. Cl. CPC C23C 16/45561; F17D 3/00; F16K 11/00; C23C 16/18

(57) ABSTRACT

Disclosed is a liquid-metal organic compound supply system which is applicable to a metal organic chemical vapor deposition (MOVCD) processing apparatus, including disposing a first bottle body in a thermostat, a second bottle body and a three-way valve in room temperature. Wherein a first connecting end of the three-way valve and a first outlet pipe of the first bottle body connect to the MOVCD processing apparatus, a second connecting end connects to a second inlet pipe of the second bottle body and a third connecting end connects to a first inlet pipe of the first bottle body and a second outlet pipe of the second bottle body. When the present invention is applied to the MOCVD manufacturing process, it prolongs usage period of trimethyl gallium, decreases replacement frequency and increases utilization ratio. Besides, the present invention also decreases the manufacturing and packing costs of trimethyl gallium.

### CROSS-REFERENCE TO RELATED APPLICATION

This application claims the benefit of Taiwan Patent Application No. 103109882, filed on Mar. 17, 2014, in the Taiwan Intellectual Property Office, the disclosure of which is incorporated herein its entirety by reference.

### BACKGROUND OF THE INVENTION

1. Field of the Invention

The present invention relates to a supply system which is applicable to metal organic chemical vapor deposition (MOCVD), in particular with respect to a liquid-metal organic compound supply system is applicable to a large scale processing apparatus for metal organic chemical vapor deposition.

2. Description of the Related Art

High purity trimethyl gallium is essential for producing photoelectron material while in the process of metal organic chemical vapor deposition (MOCVD) and is widely applied to produce semiconductor thin film material, such as compounds of GaN, GaAs, AlGaInp and so on. As high purity trimethyl gallium is characterized in better electricity, optics and magnetism, it can perform higher frequency, faster speed, lower noise and better power in semiconductor and integrated circuits. Therefore, the production techniques of the new material have been greatly applying to the fields of LED, solar cell, aviation and aerospace technology . . . etc. Pure trimethyl gallium is shaped as liquid and of high chemical activity in room temperature and will cause spontaneous combustion in the air and spontaneous explosion when contacting to water; as a result, it has to be accommodated in a tailor-made steel bottle while performing metal organic chemical vapor deposition, and the trimethyl gallium steam can reach to a desirable value by controlling the temperature of the steel bottle, and the saturated vapor pressure of trimethyl gallium in the specific temperature can be brought into the photoelectron material production system via the floating carrying gas.

However, as the growing development of metal organic chemical vapor deposition, the scale of processing apparatus which is applied to the technique gets gradually larger, and the relative stable vapor pressure for Metal Organics (MO) source is needed while being used, so that MO source steel bottle is normally placed in a thermostat for use, and because the capacity of thermostat of the existing apparatus is limited, the current trimethyl gallium packaging container is usually under 4 kg in capacity, and type of the packaging container will occur certain problems while being used, the problems mainly comprise: 1. the type of the packaging container is of relatively smaller capacity which leads to the higher finished cost as well as causes that the manufacturer of MO source keeps the packing cost up; 2. because the type of the packaging container can accommodate the relatively smaller amount of trimethyl gallium, when being applied to a large scale apparatus (e.g. Max Bright of Veeco), the usage period of single bottle can only last about 20 days, and thus, it has to make a replacement for the MO source packing container frequently, and the replacement for that will result in idle mode of the apparatus for hours and therefore decrease the productivity of MOCVD apparatus, as well as increase the percentage of incidence because of the malfunction caused by operating personnel; 3. as far as the large scale MO apparatus using a great MO source consumption is concerned, each packing container will remain a few valuable MO source which cannot be completely used. Therefore, a liquid-metal organic compound packing container customized towards a larger scale apparatus in the art has been regarding as an ultimate desire.

According to the above description, the inventor of the present invention speculates and designs a liquid-metal organic compound supply system which aims for overcoming the current technical shortcoming so as to promote the industrial applicability.

### SUMMARY OF THE INVENTION

In view of the defects of the prior art, the purpose of the present invention is to provide a liquid-metal organic compound (trimethyl gallium) supply system to solve the problems of smaller capacity of MO source container and frequent replacement for that so as to increase the production efficiency of the epitaxial wafer of the MOCVD apparatus.

According to the purpose of the present invention, it provides a liquid-metal organic compound supply system which is applicable to a metal organic chemical vapor deposition processing apparatus, comprising: a first bottle body, a second bottle body and a three-way valve. The first bottle body is used to accommodate a high purity liquid-metal organic compound, and the first bottle body has a first inlet pipe and a first outlet pipe and the first outlet pipe connects to the metal organic chemical vapor deposition processing apparatus; and the second bottle body is used to accommodate a high purity liquid-metal organic compound, and the second bottle body has a second inlet pipe, a second outlet pipe and a three-way valve, and the three-way valve has a first connecting end, a second connecting end and a third connecting end; the first connecting end connects to the metal organic chemical vapor deposition processing apparatus, the second connecting end connects to the second inlet pipe and the third connecting end connects to the first inlet pipe and the second outlet pipe, and the three-way valve connects the first connecting end with the second connecting end or the first connecting end with the third connecting end, selectively.

Preferably, the liquid-metal organic compound supply system may further comprise a liquid level gauge detecting liquid level of the first bottle body and a control module controlling the first connecting end of the three-way valve connects the second connecting end of the three-way valve when determining the liquid level of the first bottle body being lower than a first predetermined value, and the liquid level gauge being disposed in the first bottle body, the control module being electrically connected between the liquid level gauge and the three-way valve.

Preferably, the liquid-metal organic compound supply system may further comprise a display unit displaying the liquid level of the first bottle body and electrically connecting to the liquid level gauge.

Preferably, the liquid-metal organic compound supply system may further comprise a liquid level gauge detecting liquid level of the first bottle body and a control module controlling the first connecting end of three-way valve connects the third connecting end of the three-way valve when determining the liquid level of the first bottle body being higher than a second predetermined value, and the liquid level gauge being disposed in the first bottle body, the control module being electrically connected between the liquid level gauge and the three-way valve.

Preferably, the first bottle body may be disposed in a thermostat having a first temperature.

Preferably, the second bottle body may be disposed in a predetermined position having a second temperature, and the second temperature is higher than the first temperature.

Preferably, capacity of the first bottle body may be smaller than that of the second bottle body.

Preferably, the first bottle body may have a first inlet valve, a first outlet valve and a first transverse valve; the first inlet valve may be disposed in the first inlet pipe, the first outlet valve may be disposed in the first outlet pipe and the first transverse valve may be connected between the first inlet pipe and the first outlet pipe.

Preferably, the second bottle body may have a second inlet valve, a second outlet valve and a second transverse valve; the second inlet valve may be disposed in the second inlet pipe, the second outlet valve may be disposed in the second outlet pipe and the second transverse valve may be connected between the second inlet pipe and the second outlet pipe.

Preferably, the first and second bottle bodies may be a steel cylinder having three-way valve.

Preferably, the high purity liquid-metal organic compound accommodated in the first and second bottle bodies may be trimethyl gallium which is equivalent to or higher than 99.9999% in purity.

According to the purpose of the present invention, it further provides a liquid-metal organic compound supply system which is applicable to a metal organic chemical vapor deposition processing apparatus, comprising: a first bottle body, a second bottle body, a connecting pipe and a liquid level detecting module. The first bottle body is used to accommodate a high purity liquid-metal organic compound, wherein the first bottle body has a first inlet pipe and a first outlet pipe and the first outlet pipe connects to the metal organic chemical vapor deposition processing apparatus; and an end of the first inlet pipe inside the first bottle body is adjacent to bottom inside the first bottle body; the second bottle body is used to accommodate a high purity liquid-metal organic compound, wherein the second bottle body has a second inlet pipe and a second outlet pipe; and an end of the second inlet pipe inside the second bottle body is adjacent to bottom inside the second bottle body; a connecting pipe being connected between the first inlet pipe and the second outlet pipe; and the liquid level detecting module comprising a liquid level gauge detecting liquid level of the first bottle body and a display unit displaying liquid level of the first bottle body, and the liquid level gauge being disposed in the first bottle body, the display unit being electrically connected to the liquid level gauge.

Preferably, the first bottle body may be disposed in a thermostat having a first temperature.

Preferably, the second bottle body may be disposed in a predetermined position having a second temperature, and the second temperature is higher than the first temperature.

Preferably, capacity of the first bottle body may be smaller than that of the second bottle body.

Preferably, the first bottle body may have a first inlet valve, a first outlet valve and a first transverse valve; the first inlet valve may be disposed in the first inlet pipe, the first outlet valve may be disposed in the first outlet pipe and the first transverse valve may be connected between the first inlet pipe and the first outlet pipe.

Preferably, the second bottle body may have a second inlet valve, a second outlet valve and a second transverse valve; the second inlet valve may be disposed in the second inlet pipe, the second outlet valve may be disposed in the second outlet pipe and the second transverse valve may be connected between the second inlet pipe and the second outlet pipe.

Preferably, the first and second bottle bodies may be a steel cylinder having three-way valve.

Preferably, the high purity liquid-metal organic compound accommodated in the first and second bottle bodies may be trimethyl gallium which is equivalent to or higher than 99.9999% in purity.

In accordance with the aforementioned description, a liquid-metal organic compound supply system of the present invention is disposed between the first bottle body arranged in the thermostat and the second bottle body arranged in room temperature by connecting to the three-way valve, such that the second bottle body can be disposed corresponding to the structure of bottle body having a predetermined capacity which is able to decrease the packing cost of MO source effectively and prolong the usage period of trimethyl gallium used in a larger scale MOCVD processing apparatus so as to effectively decrease the consuming time of the production line for replacing the trimethyl gallium container, promote the usage efficiency of trimethyl gallium to further minimize the waste of resource in effect. Moreover, according to the arrangement of the liquid level gauge, it makes that the three-way valve switches the connection automatically so as to save the labor cost with effect. Furthermore, only via a simple and fast assemblage, a liquid-metal organic compound supply system of the present invention can connect the using steel bottle (i.e. the first bottle body) of regular size with a steel bottle (i.e. the second bottle body) of larger capacity in series without modifying the original apparatus.

### BRIEF DESCRIPTION OF THE DRAWINGS

FIG. 1 is a block schematic diagram of an embodiment of a liquid-metal organic compound supply system of the present invention.

FIG. 2 is a schematic diagram of an embodiment of arrangement for a liquid-metal organic compound supply system of the present invention.

FIG. 3 is a schematic diagram of another embodiment of arrangement for a liquid-metal organic compound supply system of the present invention.

### DETAILED DESCRIPTION OF THE PREFERRED EMBODIMENTS

Hereinafter, embodiments of the present invention will be described in detail with reference to the accompanying drawings so that those skilled in, the art to which the present invention pertains can realize the present invention. As those skilled in the art would realize, the described embodiments may be modified in various different ways, all without departing from the spirit or scope of the present invention.

With reference to the following relevant drawings, it will describe the embodiment of a liquid-metal organic compound supply system of the present invention, and for the sake of easily understanding, the same element stated in following embodiments will be described with reference to the same symbol denotation.

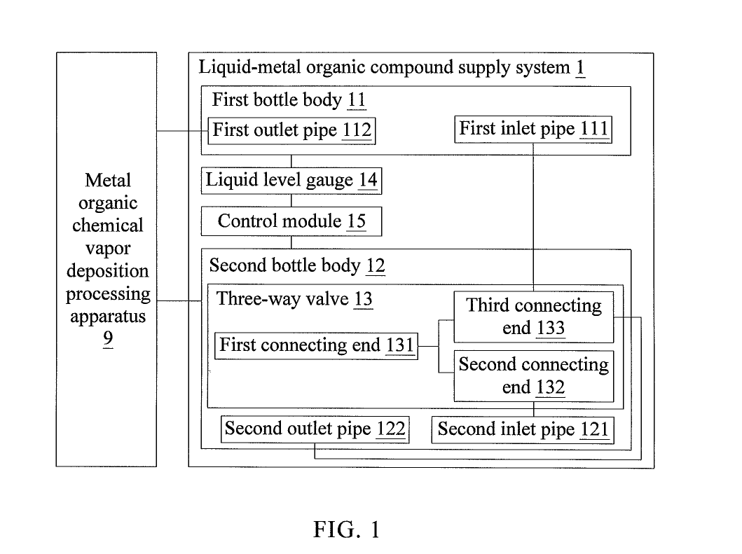

Please refer to FIG. 1, which is a block schematic diagram of an embodiment of a liquid-metal organic compound supply system of the present invention. The present invention discloses a liquid-metal organic compound supply system which aims at customizing a large scale apparatus applied to MOVCD processing apparatus for that which becomes large gradually.

As can be seen in FIG. 1, a liquid-metal organic compound supply system 1 of the present invention comprises a first bottle body 11, a second bottle body 12 and a three-way valve 13. The first 11 and second 12 bottle bodies are steel bottles which are used to accommodate a high purity liquid-metal organic compound, and preferably, trimethyl gallium is equivalent to or higher than 99.9999% in purity. Wherein, the first bottle body 11 has a first inlet pipe 111 and a first outlet pipe 112, and the first outlet pipe 112 connects to the metal organic chemical vapor deposition processing apparatus 9; and the second bottle body 12 has a second inlet pipe 121 and a second outlet pipe 122. Moreover, the three-way valve 13 has a first connecting end 131, a second connecting end 132 and a third connecting end 133; wherein the first connecting end 131 connects to the metal organic chemical vapor deposition processing apparatus 9, the second connecting end 132 connects to the second inlet pipe 121 of the second bottle body 12 and the third connecting end 133 connects to the first inlet pipe 111 of the first bottle body 11 and the second outlet pipe 122 of the second bottle body 12.

That is to say, the first bottle body 11, the second bottle body 12 and the metal organic chemical vapor deposition processing apparatus 9 are indirectly connected with each other via the three-way valve 13, and the three-way valve 13 connects the first connecting end 131 with the second connecting end 132 or the first connecting end 131 with the third connecting end 133 selectively under the specific condition. If the first connecting end 131 and the second connecting end 132 are connected, carrying gas of the metal organic chemical vapor deposition processing apparatus 9 is supplied to the second inlet pipe 121 of the second bottle body 12 for entering the second bottle body 12; and then, the carrying gas enters the first bottle body 11 via the second outlet pipe 122 of the second bottle body 12 and the first inlet pipe 111 of the first bottle body 11 and finally, enters the metal organic chemical vapor deposition processing apparatus 9 via the first outlet pipe 112 of the first bottle body 11. If the first connecting end 131 and the third connecting end 133 are connected, the carrying gas of the metal organic chemical vapor deposition processing apparatus 9 is supplied to the first inlet pipe 111 of the first bottle body 11 to enter the first bottle body 11, and to the metal organic chemical vapor deposition processing apparatus 9 via the first outlet pipe 112 of the first bottle body 11, wherein, the carrying gas may be hydrogen, nitrogen, argon or helium. By the assemblage of the three-way valve 13, a liquid-metal organic compound supply system 1 of the present invention can selectively use the steam of high purity liquid-metal organic compound accommodated in the first bottle body 11 or the first bottle body 11 and the second bottle body 12 floating into the MOVCD process via the carrying gas so as to produce compound semiconductor thin film material.

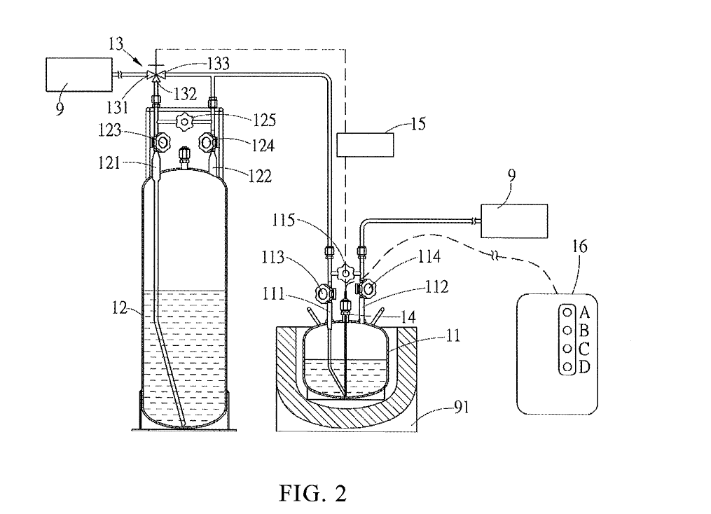

Please refer to FIG. 2, which is a schematic diagram of an embodiment of arrangement for a liquid-metal organic compound supply system of the present invention.

More specifically, the first bottle body 11 is disposed in a thermostat 91 (e.g. thermostatic tank) of the metal organic chemical vapor deposition processing apparatus 9 and is used in 5° C. temperature, and as the capacity corresponding to current thermostat 91 is limited, the capacity of the first bottle body 11 can therefore be set under 4 kg. On the other hand, the second bottle body 12 is disposed in a predetermined position in room temperature for use, and as the second bottle body 12 is not disposed in the thermostat 91, so it is free from the capacity limitation of the thermostat 91 and the capacity of the second bottle body 12 can be set above 4 kg, such as 10 kg or larger. In other words, the first bottle body 11 of a liquid-metal organic compound supply system 1 of the present invention is disposed in the thermostat 91 having a first temperature which is used to maintain in a lower temperature, and the second bottle body 12 is disposed in room temperature (i.e. in a second environmental temperature that is higher a first temperature) and capacity of the second bottle body 12 is larger than that of the first bottle body 11.

Moreover, the first bottle body 11 further comprises a first inlet valve 113, a first outlet valve 114 and a first transverse valve 115. Wherein the first inlet valve 113 and the first outlet valve 114 are respectively disposed on the first inlet pipe 111 and the first outlet pipe 112, respectively to control the floating gas in the first inlet pipe 111 and the first outlet pipe 112, individually; and the first transverse valve 115 is connected between the first inlet pipe 111 and the first outlet pipe 112. Similarly, the second bottle body 12 further comprises a second inlet valve 123, a second outlet valve 124 and a second transverse valve 125. Wherein, the second inlet valve 123 and the second outlet valve 124 are respectively disposed on the second inlet pipe 121 and the second outlet pipe 122, respectively to control the floating gas in the second inlet pipe 121 and the second outlet pipe 122, individually; and the second transverse valve 125 is connected between the second inlet pipe 121 and the second outlet pipe 122. Namely, the first 11 and second 12 bottle bodies both belong to a steel bottle having the three-way valve.

When the first 11 and second 12 bottle bodies are connected or replaced, the first inlet valve 113 and the first outlet valve 114 of the first bottle body 11 and the second inlet valve 123 and the second outlet valve 124 of the second bottle body 12 are turned off, and then to connect the bottle bodies 11, 12 and the three-way valve 13. Next, the first transverse valve 115 of the first bottle body 11 and the second transverse valve 125 of the second bottle body 12 are turned on to completely eliminate the air contained in the pipes via the carrying gas to ensure that there is no oxygen and water therein, and finally, turning on the first inlet valve 113 and the first out valve 114 of the first bottle body 11 and the second inlet valve 123 and the second outlet valve 124 of the second bottle body 12, and it can be used as usual. That is to say, the purpose of disposing a three-way valve on the first 11 and second 12 bottle bodies is to eliminate the air contained in the pipes while connecting the first bottle body 11 and the second bottle body 12 in series. Because MO source is high purity electronic material and is sensitive to water and oxygen and other impurities, it has to completely eliminate the air contained in the connected pipes to avoid the MO source from being polluted by the impurity in the air. If without the three-way valve, the pipes connected between the second outlet pipe 122 of the second bottle body 12 and the first inlet pipe 111 of the first bottle body 11 are not able to eliminate the air contained in therein. Simply speaking, while turning on the transverse valves 115, 125 of the two steel bottles and turning off the other valves 113, 114, 123, 124, the pipes which connect to the first 11 and second 12 bottle bodies are conducted so as to proceed with vacuum exchange and thus the gas is not able to enter the first 11 and second 12 bottle bodies. When the elimination of air is completed, it can turn off the two transverse valves 115, 125 and turn on the other valves 113, 114, 123, 124, and it can therefore be used as usual.

Besides, as the temperature for using MO source is 5° C., that is, the first bottle body 11 is used in that temperature and the second bottle body 12 is used in room temperature. And as the vapor pressure is of higher difference in the two temperatures, while the first 11 and second 12 bottle bodies are used simultaneously, the first bottle body 11 will cause condensation as the lower temperature, so that the MO source will be condensed as liquid in the first bottle body 11 gradually and overflows. Therefore, a liquid-metal organic compound supply system 1 of the present invention further comprises a liquid level gauge 14 and a control module 15. The liquid level gauge 14 is disposed on the first bottle body 11 and the control module 15 is electrically connected between the three-way valve 13 and the liquid level gauge 14 to control the three-way valve 13 connecting the first connecting end 13 with the second connecting end 132 of the three-way valve 13 or the first connecting end 131 with the third connecting end 133 of the three-way valve 13, selectively.

More specifically, the liquid level gauge 14 has a first predetermined value (lower liquid level value) and a second predetermined value (higher liquid level value). When the liquid level gauge 14 detects that the liquid level in the first bottle body 11 is lower than the first predetermined value, the liquid level gauge 14 feedbacks a first control signal to the control module 15 so that the control module 15 can control the three-way valve 13 connecting the first connecting end 131 with the second connecting end 132 to supply the carrying gas to the second bottle body 12 for connecting the two bottle bodies 11, 12 in series. Because of the condensation, the liquid level in the first bottle body 11 will rise gradually in the process of utilization. When the liquid level gauge 14 detects that the liquid level in the first bottle body 11 is higher than the second predetermined value, the second control signal is therefore transmitted to the control module 15 so that the control module 15 can control the three-way valve 13 connecting the first connecting end 131 with the third connecting end 133. Under the circumstance of the first connecting end 131 and the third connecting end 133 are connected, the carrying gas which is supplied to the second bottle body 12 will be cut off and turns into supplying gas to the first bottle body 11, directly; and only while in the process of using the first bottle body 11, the liquid level of the liquid in the first bottle body 11 is gradually lowered because of the lack of condensation. When the liquid level in the first bottle body 11 is lower than the first predetermined value, the carrying gas is supplied to the second bottle body 12. That is, by the liquid level gauge 14, the three-way valve 13 can switch repeatedly corresponding to the liquid level of the first bottle body 11. In addition, it is noticeable that the liquid level gauge 14 further comprises a third predetermined value which is lower than the first predetermined value. Namely, when the second bottle body 12 runs out of MO source, the liquid level of the first bottle body 11 will keep decreasing, and when the liquid level gauge 14 detects that the liquid level of the first bottle body 11 is lower than the third predetermined value (the lowest liquid level), the control module 15 controls a display unit 16 or the control module 15 itself sending information to notify the operating personnel to replace the bottle body, such as the replacement for the second bottle body 12. According to the aforementioned description, preferably, the control module 15 can be Programmable Logic Controller (PLC). Besides, a fourth predetermined value is also included. The fourth predetermined is used to keep notifying the operating personnel turning the valve off manually to stop the supplement while the liquid level reaches to the second predetermined value but fails to stop supplying because of the malfunction.

By means of a liquid-metal organic compound supply system 1 of the present invention, it can wholly change or break the inherent though which indicates that MO source steel bottle has to be disposed in the thermostat 91, such that the second bottle body 12 is free from the limitation of capacity of the thermostat 91 and proceeds to make a larger size manufacture. It is noteworthy that a liquid-metal organic compound supply system 1 of the present invention further comprises the display unit 16 which is electrically connected to the liquid level gauge 14 to display the liquid level of the first bottle body 11 for benefiting the user from observing.

In addition, the following is the exemplary explanation of an aspect of the present embodiment based on the display unit 16. Wherein point A that the display unit 16 displays is the fourth predetermined value, point B is the second predetermined value, point C is the first predetermined value and point D indicates the third predetermined value. As FIG. 2 shows, when the display unit 16 displays that the liquid level reaches to point C (the first predetermined value), the liquid-metal organic compound supply system 1 executes the supplement automatically, and while the display unit 16 displays that the liquid level reaches to point B (the second predetermined value), the liquid-metal organic compound supply system 1 stops supplying automatically.

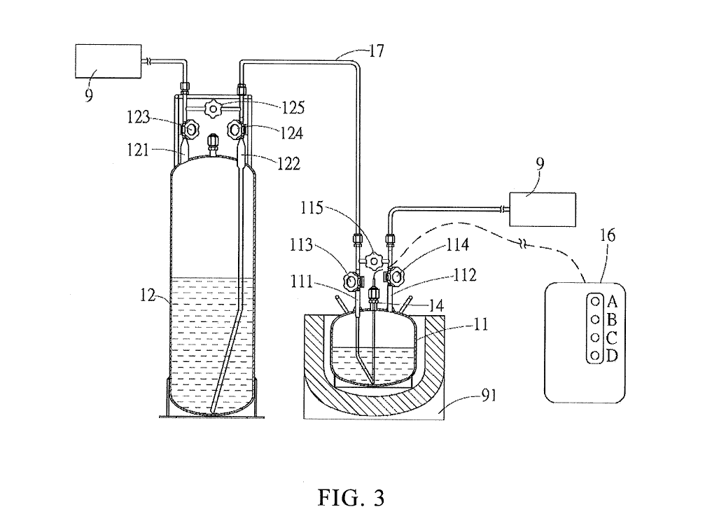

Please refer to FIG. 3, which is a schematic diagram of another embodiment of arrangement for a liquid-metal organic compound supply system of the present invention. The correlation and assemblage with each element of the same symbol stated in the present embodiment are similar to the former embodiment, and the unnecessary detailed description of similarity thereof is no longer given.

As FIG. 3 shows, the main difference between the present embodiment and the former depends on the second outlet pipe 122 of the second bottle body 12. In the former embodiment, the second inlet pipe 121 and the second outlet pipe 122 of the second bottle body 12 are adjacent to a bottom of an accommodating space inside the second bottle body 12 where is an end of the second inlet pipe 121 (as shown in FIG. 2), and an end of the second outlet pipe 122 of the second bottle body 12 stated in the present embodiment is adjacent to the bottom of the accommodating space inside the second bottle body 12.

More specifically, a liquid-metal organic compound supply system 1 of the present invention comprises the first bottle body 11, the second bottle body 12, the connecting pipe 17 and a liquid level detecting module comprising the liquid level gauge 14 and the display unit 16. Wherein, the connecting pipe 17 is ¼″ VCR connecting pipe which is connected between the first inlet pipe 111 and the second outlet pipe 122. Besides, both ends of the connecting pipe 17 is a female connector corresponding to ports of the first inlet pipe 111 and the second outlet pipe 122, but it shall not be subject to this restriction. In addition, the display unit 16 is electrically connected to the liquid level gauge 14 for displaying the liquid level of the first bottle body 11, for example, data line RS 232 of the liquid level gauge 14 is connected to the display unit 16. Similarly, the display unit 16 displays the liquid level of the first bottle body 11 by 4 graduations (A, B, C, D) in the present embodiment, but it shall not be subject to this restriction.

In the practical application and normal situation, the second transverse valve 125 of the second bottle body 12 is turned on and the second inlet valve 123 and the second outlet valve 124 are turned off, and then the first transverse valve 125 of the first bottle body 11 is turned off and the first inlet valve 113 and the first outlet valve 114 are turned on. At this time, the carrying gas floats directly to the first bottle body 11 via the second transverse valve 125 without entering the second bottle body 12; namely, only the first bottle body is used. In the aspect of the present embodiment, because there is no the control module 15, when the display unit 16 displays that the liquid level reaches to point C (the first predetermined value), the operating personnel shall make the supplement when the apparatus is turned off, and the display unit 16 displays that the liquid level reaches to point B (the second predetermined value) after the supplement is completed, the supplement to liquid is therefore stopped.

It is noteworthy to mention that the first bottle body 11 and the thermostat 91 are a thermostatic tank originally assembled in a MOCVD apparatus and a steel bottle used under normal circumstance (usually is 4 kg or 2.5 kg). Because the current MOCVD apparatuses become larger, and the usage amount of MO source raises which causes that the usage time for the regular size MO source steel bottle is shortened and the frequency of the replacement for MO source steel bottle is therefore increased. It takes time to replace the empty steel bottle with a full one in which the production is ceased temporarily, such that the production efficiency is degraded and therefore increases the unit cost of epitaxial wafer indirectly. However, as the usage amount of MO source brought out by the carrying gas used in the MOCVD apparatus needs to be maintained in stability, consequently, if a steel bottle of larger size is desirable, once it exceeds in the original accommodating capacity of the thermostatic tank, another thermostatic tank corresponding to the larger steel bottle is necessitated to ensure the temperature of the steel bottle, so that the usage amount of MO source brought out by the carrying gas can stay in stability. Making a thermostatic tank corresponding to the steel bottle belongs to an expensive engineering project and will cost hugely, and it also has to relocate the arrangement of MO source steel bottle and the thermostatic tank used in the MOCVD apparatus because that the thermostatic tank's area is modified. As to the present invention, only via a simple and fast assemblage, it thereby connects the original steel bottle of normal size with a steel bottle of larger capacity in series, i.e. the second bottle body 12 (capacity size of the second bottle body can be customized based on inner space of apparatus), and the second bottle body 12 is used in room temperature without using the thermostatic tank according to the aforementioned arrangement. The design used in room temperature is a breakthrough in the art (using steel bottle is necessitated). The saturated vapor of MO source brought out by the second bottle body 12 is in constant temperature while floating through a small steel bottle; at this time, the saturated vapor pressure is that used in the temperature of the small steel bottle (usage temperature of trimethyl gallium is usually in 5° C.).

In summary, a liquid-metal organic compound supply system of the present invention is characterized of simple structural configuration, easy to manufacture and assemble and convenient for transporting and so on and so forth. In addition, the main feature of the present invention lies in that user can keep using MO source in a long duration without modifying MOCVD apparatus and working environment so as to lower the non-production time because of the replacement for the empty MO source steel bottle, so the production efficiency can be promoted and the production cost can be decreased. Moreover, as the arrangement of the liquid level gauge, the three-way valve can switch automatically without being interfered with manpower, and the second bottle body is free from capacity limitation of the thermostat, steel bottle of larger size can be manufactured to lower the replacement times for steel bottle greatly so as to promote production efficiency of apparatus and decrease the failure rate caused by operating personnel. As a result, a liquid-metal organic compound supply system of the present invention is not only of prominent economic benefits, but also with fine practical applicability.

While the means of specific embodiments in present invention has been described by reference drawings, numerous modifications and variations could be made thereto by those skilled in the art without departing from the scope and spirit of the invention set forth in the claims. The modifications and variations should in a range limited by the specification of the present invention.

What is claimed is:

1. A liquid-metal organic compound supply system applicable to a metal organic chemical vapor deposition processing apparatus, comprising:
a first bottle body accommodating a high purity liquid-metal organic compound, wherein the first bottle body has a first inlet pipe and a first outlet pipe and the first outlet pipe connects to the metal organic chemical vapor deposition processing apparatus; and
a second bottle body accommodating a high purity liquid-metal organic compound, wherein the second bottle body has a second inlet pipe, a second outlet pipe and a three-way valve, and the three-way valve has a first connecting end, a second connecting end and a third connecting end; the first connecting end connects to the metal organic chemical vapor deposition processing apparatus, the second connecting end connects to the second inlet pipe and the third connecting end connects to the first inlet pipe and the second outlet pipe, and the three-way valve connects the first connecting end with the second connecting end or the first connecting end with the third connecting end, selectively.

2. The liquid-metal organic compound supply system as defined in claim 1, wherein the liquid-metal organic compound supply system further comprises a liquid level gauge detecting liquid level of the first bottle body and a control module controlling the first connecting end of the three-way valve connects the second connecting end of the three-way valve when determining the liquid level of the first bottle body being lower than a first predetermined value, and the liquid level gauge being disposed in the first bottle body, the control module being electrically connected between the liquid level gauge and the three-way valve.

3. The liquid-metal organic compound supply system as defined in claim 2, further comprising a display unit displaying the liquid level of the first bottle body and electrically connecting to the liquid level gauge.

4. The liquid-metal organic compound supply system as defined in claim 1, wherein the liquid-metal organic compound supply system further comprises a liquid level gauge detecting liquid level of the first bottle body and a control module controlling the first connecting end of the three-way valve connects the third connecting end of the three-way valve when determining the liquid level of the first bottle body being higher than a second predetermined value, and the liquid level gauge being disposed in the first bottle body, the control module being electrically connected between the liquid level gauge and the three-way valve.

5. The liquid-metal organic compound supply system as defined in claim 1, wherein the first bottle body is disposed in a thermostat having a first temperature.

6. The liquid-metal organic compound supply system as defined in claim 5, wherein the second bottle body is disposed in a predetermined position having a second temperature, and the second temperature is higher than the first temperature.

7. The liquid-metal organic compound supply system as defined in claim 1, wherein capacity of the first bottle body is smaller than that of the second bottle body.

8. The liquid-metal organic compound supply system as defined in claim 1, wherein the first bottle body has a first inlet valve, a first outlet valve and a first transverse valve; the first inlet valve is disposed in the first inlet pipe, the first outlet valve is disposed in the first outlet pipe and the first transverse valve is connected between the first inlet pipe and the first outlet pipe.

9. The liquid-metal organic compound supply system as defined in claim 1, wherein the second bottle body has a second inlet valve, a second outlet valve and a second transverse valve; the second inlet valve is disposed in the second inlet pipe, the second outlet valve is disposed in the second outlet pipe and the second transverse valve is connected between the second inlet pipe and the second outlet pipe.

10. The liquid-metal organic compound supply system as defined in claim 1, wherein the first and second bottle bodies are a steel cylinder having three-way valve.

11. The liquid-metal organic compound supply system as defined in claim 1, wherein the high purity liquid-metal organic compound accommodated in the first and second bottle bodies is trimethyl gallium which is equivalent to or higher than 99.9999% in purity.

12. A liquid-metal organic compound supply system applicable to a metal organic chemical vapor deposition processing apparatus, comprising:
a first bottle body accommodating a high purity liquid-metal organic compound, wherein the first bottle body has a first inlet pipe and a first outlet pipe and the first outlet pipe connects to the metal organic chemical vapor deposition processing apparatus; and an end of the first inlet pipe inside the first bottle body is adjacent to bottom inside the first bottle body;
a second bottle body accommodating a high purity liquid-metal organic compound, wherein the second bottle body has a second inlet pipe and a second outlet pipe; and an end of the second inlet pipe inside the second bottle body is adjacent to bottom inside the second bottle body;
a connecting pipe being connected between the first inlet pipe and the second outlet pipe; and
a liquid level detecting module comprising a liquid level gauge detecting liquid level of the first bottle body and a display unit displaying liquid level of the first bottle body, and the liquid level gauge being disposed in the first bottle body, the display unit being electrically connected to the liquid level gauge.

13. The liquid-metal organic compound supply system as defined in claim 12, wherein the first bottle body is disposed in a thermostat having a first temperature.

14. The liquid-metal organic compound supply system as defined in claim 13, wherein the second bottle body is disposed in a predetermined position having a second temperature, and the second temperature is higher than the first temperature.

15. The liquid-metal organic compound supply system as defined in claim 12, wherein capacity of the first bottle body is smaller than that of the second bottle body.

16. The liquid-metal organic compound supply system as defined in claim 12, wherein the first bottle body has a first inlet valve, a first outlet valve and a first transverse valve; the first inlet valve is disposed in the first inlet pipe, the first outlet valve is disposed in the first outlet pipe and the first transverse valve is connected between the first inlet pipe and the first outlet pipe.

17. The liquid-metal organic compound supply system as defined in claim 12, wherein the second bottle body has a second inlet valve, a second outlet valve and a second transverse valve; the second inlet valve is disposed in the second inlet pipe, the second outlet valve is disposed in the second outlet pipe and the second transverse valve is connected between the second inlet pipe and the second outlet pipe.

18. The liquid-metal organic compound supply system as defined in claim 12, wherein the first and second bottle bodies are a steel cylinder having three-way valve.

19. The liquid-metal organic compound supply system as defined in claim 12, wherein the high purity liquid-metal organic compound accommodated in the first and second bottle bodies is trimethyl gallium which is equivalent to or higher than 99.9999% in purity.
